(19) United States
(12) Patent Application Publication
(10) Pub. No.: US 2026/0150645 A1
(43) Pub. Date: May 28, 2026

(54) SEMICONDUCTOR DEVICE AND PACKAGE STRUCTURE

(71) Applicant: TAIWAN SEMICONDUCTOR MANUFACTURING COMPANY LTD., HSINCHU (TW)

(72) Inventors: HUNG-LI CHIANG, TAIPEI CITY (TW); WEI-CHENG LIN, TAICHUNG CITY (TW); JIANN-TYNG TZENG, HSINCHU (TW)

(21) Appl. No.: 18/959,709

(22) Filed: Nov. 26, 2024

(51) Int. Cl. H01L 23/528; H01L 23/522; H10D 84/85

(52) U.S. Cl. CPC H10W 20/427; H10D 84/856; H10W 20/42; H10W 20/435

(57) ABSTRACT

A semiconductor device and a package structure are provided. The semiconductor device includes an integrated circuit, a first power delivery network, and a second power delivery network. The integrated circuit includes at least a complementary field effect transistor. The semiconductor device has a first side and a second side on opposite sides of the complementary field effect transistor. The first power delivery network is configured to provide a first power supply voltage from the first side of the semiconductor device to the integrated circuit. The second power delivery network is configured to provide a second power supply voltage from the second side of the semiconductor device to the integrated circuit.

### BACKGROUND

Integrated circuits need to deliver power to different parts of the integrated circuits. The integrated circuits also need to deliver power in efficient ways. The integrated circuits may include different conductive structures and paths for power delivery.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a perspective view of a semiconductor structure according to one or more embodiments of the present disclosure.

FIG. 1B is a perspective view of a semiconductor structure according to one or more embodiments of the present disclosure.

FIG. 2 is a cross-section of a semiconductor device according to one or more embodiments of the present disclosure.

FIG. 3 is a cross-section of a package structure according to one or more embodiments of the present disclosure.

FIG. 4 is a cross-section of a package structure according to one or more embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

For integrated circuits, power may need to be delivered to different sides of the integrated circuits. For example, a complementary field effect transistor (CFET) integrated circuit includes p-channel metal-oxide-semiconductor (PMOS) field-effect transistors and n-channel metal-oxide-semiconductor (NMOS) field-effect transistors. The PMOS and NMOS transistors are stacked vertically with common gates. This structure simplifies access to the transistors. However, such a structure requires power to be delivered to two sides of the CFET integrated circuit.

Embodiments of the present disclosure discuss a semiconductor device including CFETs and power delivery networks or power grids configured to provide power supply voltages to the CFETs from opposite sides of the semiconductor device. With the above design, the arrangements of power vias or power taps for coupling power rails at opposite sides of the CFETs can be omitted. Therefore, there is no need to reserve spaces within the layouts or routing structures for the power vias or power taps, more areas can be used for routing, and thus the routing flexibility and the routing density can be increased.

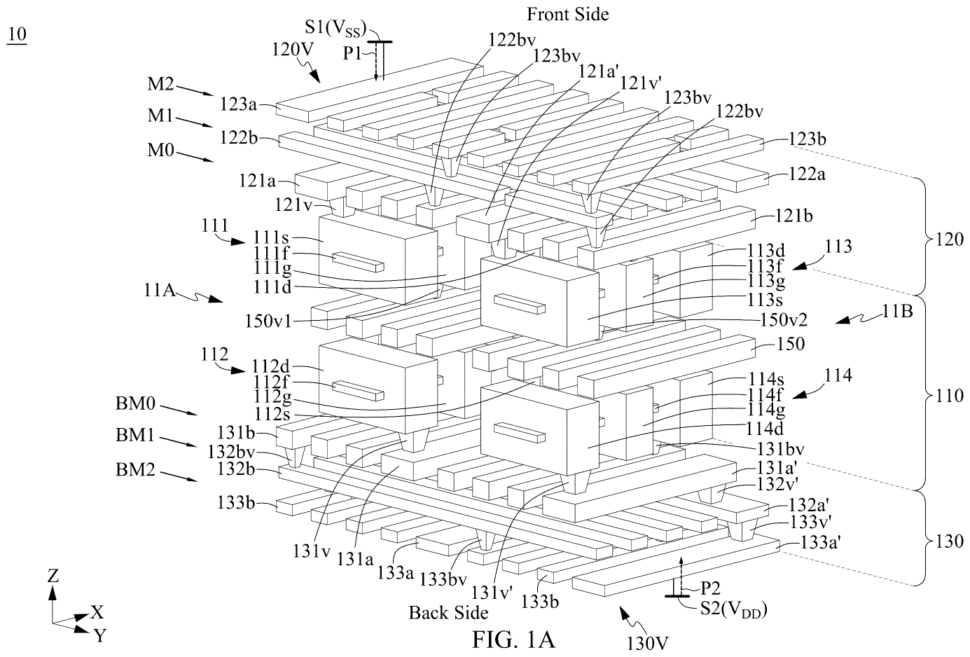

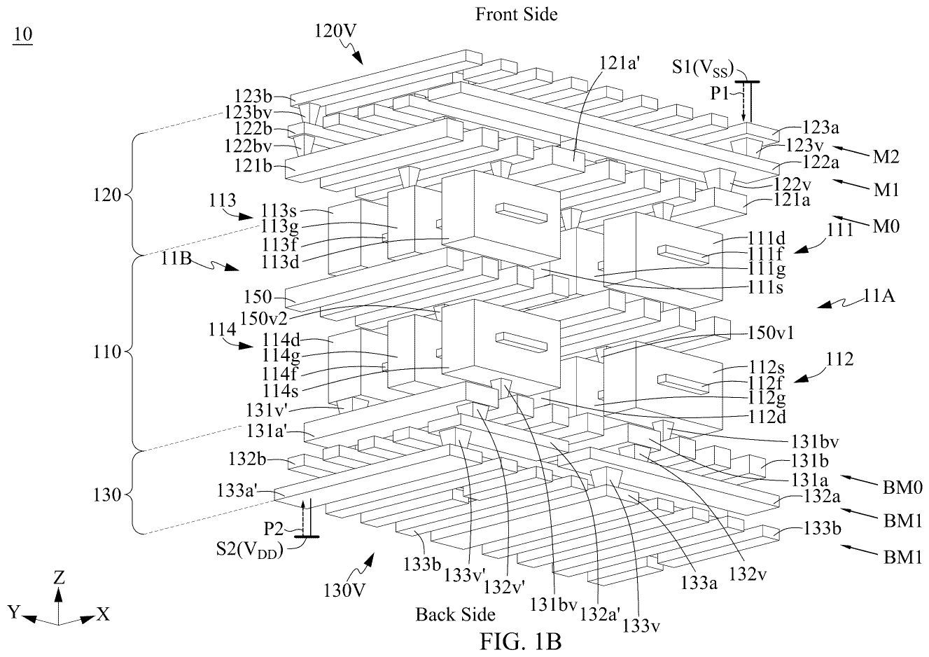

FIG. 1A is a perspective view of a semiconductor structure 10 according to one or more embodiments of the present disclosure. FIG. 1B is a perspective view of a semiconductor structure 10 according to one or more embodiments of the present disclosure. In some embodiments, FIG. 1A and FIG. B are perspective views of the semiconductor structure 10 from different angles. The perspective views of the semiconductor structure 10 are in a three-dimensional representation with x, y, and z reference axes. The semiconductor structure 10 may include an integrated circuit 110 and interconnection structures 120 and 130. The semiconductor structure 10 may be referred to as a semiconductor device or a partial structure of a semiconductor device. The semiconductor device may be or include a logic die.

The integrated circuit 110 may include one or more complementary field effect transistors (CFETs). In some embodiments, the integrated circuit 110 includes CFETs 11A and 11B. In some embodiments, the CFET 11A includes a FET 111 and a FET 112 stacked vertically along the z direction with common gates. The FET 111 may include a fin 111f having a channel region and source/drain regions, a gate structure 111g wrapping around the channel region of the fin 111f, a source contact 111s wrapping around the source region of the fin 111f, and a drain contact 111d wrapping around the drain region of the fin 111f. The FET 112 may include a fin 112f having a channel region and source/drain regions, a gate structure 112g wrapping around the channel region of the fin 112f, a source contact 112s wrapping around the source region of the fin 112f, and a drain contact 112d wrapping around the drain region of the fin 112f. The FET 111 may include an NMOS transistor, and the FET 112 may include a PMOS transistor. The gate structure 111g may be electrically connected to the gate structure 112g through a conductive via 150v1. In some embodiments, the CFET 11B includes a FET 113 and a FET 114 stacked vertically along the z direction with common gates. The FET 113 may include a fin 113f having a channel region and source/drain regions, a gate structure 113g wrapping around the channel region of the fin 113f, a source contact 113s wrapping around the source region of the fin 113f, and a drain contact 113d wrapping around the drain region of the fin 113f. The FET 114 may include a fin 114f having a channel region and source/drain regions, a gate structure 114g wrapping around the channel region of the fin 114f, a source contact 114s wrapping around the source region of the fin 114f, and a drain contact 114d wrapping around the drain region of the fin 114f. The FET 113 may include an NMOS transistor, and the FET 114 may include a PMOS transistor. The gate structure 113g may be electrically connected to the gate structure 114g through a conductive via 150v2.

In some embodiments, the integrated circuit 110 further includes metal layers 150. The metal layers may be referred to as interleaved metals. In some embodiments, the gate structure 113g is electrically connected to the gate structure 114g through one of the metal layers 150. Additional vias may be formed between one or more of the metal layers 150 and one or more of the FETs 111, 112, 113, and 114.

In some embodiments, the semiconductor structure 10 (or semiconductor device) may has a first side (or a front side) and a second side (or a backside) on opposite sides of the CFETs 11A and 11B. The semiconductor structure 10 (or semiconductor device) may be configured to receive a first power supply voltage and a second power supply voltage, respectively, from a plurality of power sources outside of the semiconductor device. In some embodiments, the semiconductor structure 10 (or semiconductor device) is configured to receive the first power supply voltage from a voltage source S1 (V_{SS}). In some embodiments, the semiconductor structure 10 (or semiconductor device) is configured to receive the second power supply voltage from a voltage source S2 (V_{DD}). The first power supply voltage may be provided from the front side of the semiconductor structure 10 (or semiconductor device) to the integrated circuit 110 along a path P1, and the second power supply voltage may be provided from the back side of the semiconductor structure 10 (or semiconductor device) to the integrated circuit 110 along a path P2.

The interconnection structure 120 may include power lines 121a, 121a′, 122a, and 123a, signal lines 121b, 122b, and 123b, power vias 121v, 121v′, 122v, and 123v, and signal vias 121bv, 122bv, and 123bv. The power lines may be referred to as power rails. In some embodiments, the power vias 121v is coupled between the power line 121a and the CFET 11A, and the power vias 121v′ is coupled between the power line 121a′ and the CFET 11B. In some embodiments, the signal lines 121b, 122b, and 123b are coupled to the integrated circuit 110. In some embodiments, the signal vias 121bv are coupled between the signal lines 121b and the CFETs 11A and 11B. In some embodiments, a width of the signal lines 121b, 122b, and 123b is less than a width of the power lines 121a, 121a′, 122a, and 123a. In some embodiments, a width of the signal vias 121bv, 122bv, and 123bv is less than a width of the power vias 121v, 121v′, 122v, and 123v.

In some embodiments, the power lines 121a, 121a′ and the signal lines 121b are at the same elevation. As shown in FIG. 1A and FIG. 1B, the power lines 121a, 121a′ and the signal lines 121b are in a first metal line (e.g., M0) at the front side of the integrated circuit 110. In some embodiments, the power line 122a and the signal lines 122b are at the same elevation. As shown in FIG. 1A and FIG. 1B, the power line 122a and the signal lines 122b are in a second metal line (e.g., M1) at the front side of the integrated circuit 110. In some embodiments, the power line 123a and the signal lines 123b are at the same elevation. As shown in FIG. 1A and FIG. 1B, the power line 123a and the signal lines 123b are in a third metal line (e.g., M2) at the front side of the integrated circuit 110. The signal lines 121b, 122b, and 123b and the signal vias 121bv, 122bv, and 123bv may construct a signal routing structure at the front side of the integrated circuit 110.

In some embodiments, the interconnection structure 120 is configured to receive a first power supply voltage from the front side (or the first side) of the semiconductor structure 10 (or the semiconductor device). In some embodiments, the interconnection structure 120 includes a first power delivery network 120V configured to provide a first power supply voltage from the front side (or the first side) of the semiconductor structure 10 (or the semiconductor device) to the integrated circuit 110. The first power delivery network 120V can be a power grid (PG) or a front side power grid arranged to transmit power for the integrated circuit 110. The first power delivery network 120V (or the power grid) may be configured to receive the first power supply voltage. The first power delivery network 120V may be at a front side (or a first side) of the integrated circuit 110. The first power delivery network 120V may include at least the power lines 121a, 121a′, 122a, 123a and the power vias 121v, 122v, and 123v. The first power supply voltage may be a voltage of ground level or a voltage source supply (V_{SS}). The first power supply voltage may be a negative voltage level (i.e., V_{SS}).

The interconnection structure 130 may include power lines 131a, 131a′, 132a, 132a′, 133a, and 133a′, signal lines 131b, 132b, and 133b, power vias 131v, 131v′, 132v, 132v′, 133v, and 133v′, and signal vias 131bv, 132bv, and 133bv. The power lines may be referred to as power rails. In some embodiments, the signal lines 131b, 132b, and 133b are coupled to the integrated circuit 110. In some embodiments, a width of the signal lines 131b, 132b, and 133b is less than a width of the power lines 131a, 131a′, 132a, 132a′, 133a, and 133a′.

In some embodiments, the power lines 131a, 131a′ and the signal lines 131b are at the same elevation. As shown in FIG. 1A and FIG. 1B, the power lines 131a, 131a′ and the signal lines 131b are in a first metal line (e.g., BM0) at the back side of the integrated circuit 110. In some embodiments, the power line 132a, 132a′ and the signal lines 132b are at the same elevation. As shown in FIG. 1A and FIG. 1B, the power line 132a, 132a′ and the signal lines 132b are in a second metal line (e.g., BM1) at the back side of the integrated circuit 110. In some embodiments, the power line 133a, 133a′ and the signal lines 133b are at the same elevation. As shown in FIG. 1A and FIG. 1B, the power line 133a, 133a′ and the signal lines 133b are in a third metal line (e.g., BM2) at the back side of the integrated circuit 110. The signal lines 131b, 132b, and 133b and the signal vias 131bv, 132bv, and 133bv may construct a signal routing structure at the back side of the integrated circuit 110.

In some embodiments, the interconnection structure 130 is configured to receive a second power supply voltage from the back side (or the second side) of the semiconductor structure 10 (or the semiconductor device). In some embodiments, the interconnection structure 130 includes a second power delivery network 130V configured to provide a second power supply voltage from the back side (or the second side) of the semiconductor structure 10 (or the semiconductor device) to the integrated circuit 110. The second power delivery network 130V can be a power grid (PG) or a back side power grid arranged to transmit power for the integrated circuit 110. The second power delivery network 130V (or the power grid) may be configured to receive the second power supply voltage. The second power delivery network 130V may be at a back side (or a second side) of the integrated circuit 110. The second power delivery network 130V may include at least the power lines 131a, 131a′, 132a, 132a′, 133a, and 133a′ and the power vias 131v, 131v′, 132v, 132v′, 133v, and 133v′. The second power supply voltage may be a positive voltage level (i.e., V_{DD}).

In some embodiments, the power lines 121a, 121a′, 131a, and 131a′ extend substantially in parallel. In some embodiments, the power lines 122a, 132a, and 132a′ extend substantially in parallel. In some embodiments, the power lines 123a, 133a, and 133a′ extend substantially in parallel. In some embodiments, the semiconductor structure 10 (or the semiconductor device) is free of a power via configured to provide power from the first power delivery network 120V to the second power delivery network 130V.

In some embodiments, the first power delivery network 120V (or the power grid) is coupled between the front side (or the first side) of the semiconductor structure 10 (or the semiconductor device) and the CFETs 11A and 11B, and the second power delivery network 130V (or the power grid) is coupled between the back side (or the second side) of the semiconductor structure 10 (or the semiconductor device) and the CFETs 11A and 11B. In some embodiments, a ratio of an amount of routing resource taken by the first power delivery network 120V (or the power grid) to an amount of routing resource taken by the second power delivery network 130V (or the power grid) is from about 80% to about 120%, from about 85% to about 115%, from about 90% to about 110%, from about 95% to about 105%, or about 100%.

Conventionally, power supply voltages (e.g., V_{SS} and V_{DD}) are provided from a single side of a semiconductor device or a die to the integrated circuit therein. For a device including CFETs with I/O terminals on opposite sides, a power via is required to couple a power source from one side of the CFETs to a power rail at an opposite side of the CFETs. For example, the backside of the CFETs may be directly coupled to a positive voltage level (i.e., V_{DD}) at the backside of the CFETs, and one or more power vias may be used to couple a negative voltage level (i.e., V_{SS}) at the backside to a power rail at the front side of the CFETs so as to provide the negative supply voltage to the front side of the CFETs. However, the arrangements of the power vias may degrade the routing resource, and IR drop in the power distribution network may undesirably increase.

According to some arrangements of the present disclosure, the semiconductor device includes power delivery networks or power grids configured to provide power supply voltages to the CFETs from opposite sides of the semiconductor device. Therefore, the arrangements of power vias or power taps for coupling power rails at opposite sides of the CFETs can be omitted. Therefore, there is no need to reserve spaces within the layouts or routing structures (e.g., the interconnection structures 120 and 130) for the power vias or power taps, more areas can be used for routing, and thus the routing flexibility and the routing density can be increased.

In addition, when power vias are arranged to couple power rails at opposite sides of the CFETs, the relatively long path of the power vias may induce IR drop and degrade the gate density. In contrast, according to some arrangements of the present disclosure, the semiconductor device is free of a power via configured to provide power from the one power delivery network to another power delivery network at an opposite side. Therefore, IR drop in the power distribution network can be reduced significantly, resulting in better voltage regulation and improved overall efficiency of the circuit.

Moreover, according to some arrangements of the present disclosure, an amount of routing resource taken by the power grid at the front side is close or substantially equal to an amount of routing resource taken by the power grid at the back side. Therefore, since the power routings at both of the front side and the back side are reduced in amounts and are balanced arranged, the flexibility as well as the amounts of signal routings at the front side and the back side of the semiconductor device can be increased, and thus the routing density can be increased accordingly.

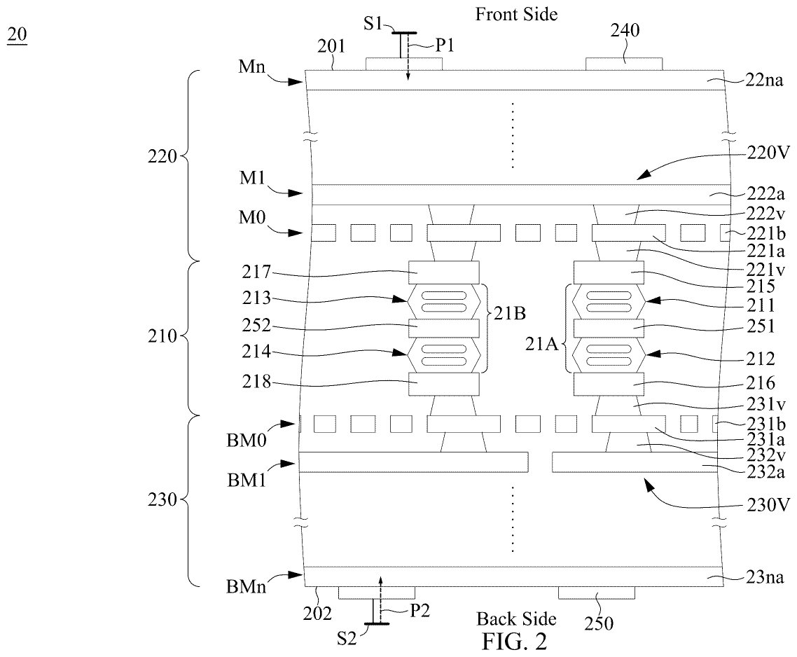

FIG. 2 is a cross-section of a semiconductor device 20 according to one or more embodiments of the present disclosure. The semiconductor device 20 illustrated in FIG. 2 is similar to the semiconductor structure 10 illustrated in FIG. 1A and FIG. 1B, and the differences therebetween are described as follows.

The semiconductor device 20 may include an integrated circuit 210, interconnection structures 220 and 230 at opposite sides of the integrated circuit 210, and terminals 240 and 250 at opposite sides of the semiconductor device 20. The terminals 240 and 250 may be or include conductive pads. In some embodiments, the terminal 240 is exposed by or disposed on a surface 201 of the semiconductor device 20, and the terminal 250 is exposed by or disposed on a surface 202 of the semiconductor device 20. The semiconductor device 20 may be or include a logic die.

The integrated circuit 210 may include one or more CFETs. In some embodiments, the integrated circuit 110 includes CFETs 21A and 21B.

In some embodiments, the CFET 21A includes a FET 211 and a FET 212 stacked vertically along the z direction with common gates. The FET 211 may include an NMOS transistor, and the FET 212 may include a PMOS transistor. In some embodiments, a metal diffusion local interconnector (MDLI) 251 is coupled between the FET 211 and the FET 212. In some embodiments, the CFET 21A is coupled to the interconnection structure 220 through a metal diffusion (MD) layer 215, and the CFET 21A is coupled to the interconnection structure 230 through a MD layer 216.

In some embodiments, the CFET 21B includes a FET 213 and a FET 214 stacked vertically along the z direction with common gates. The FET 213 may include an NMOS transistor, and the FET 214 may include a PMOS transistor. In some embodiments, a MDLI 252 is coupled between the FET 213 and the FET 214. In some embodiments, the CFET 21B is coupled to the interconnection structure 220 through a MD layer 217, and the CFET 21B is coupled to the interconnection structure 230 through a MD layer 218.

In some embodiments, the interconnection structure 220 includes a first power delivery network 220V configured to provide a first power supply voltage from the front side (or the first side) of the semiconductor device 20 to the integrated circuit 210. The first power delivery network 220V includes a plurality of power lines (e.g., power lines 221a, 222a, and 22na) and a plurality of power vias (e.g., power vias 221v and 222v) coupled between the integrated circuit 210 and the terminals 240 at the front side. The power lines may be or include n layers of metal layers (e.g., M1, M2, and Mn, n may be an integer greater than 3). The first power supply voltage may be a voltage of ground level or a voltage source supply (V_{SS}). The first power supply voltage may be a negative voltage level (i.e., V_{SS}).

In some embodiments, the interconnection structure 220 further includes signal lines (e.g., signal lines 221b). The signal lines may be or include n layers of metal layers (e.g., M1, M2, and Mn, n may be an integer greater than 3). Each of the signal lines may be at the same elevation with one layer of the power lines.

In some embodiments, the interconnection structure 230 includes a second power delivery network 230V configured to provide a second power supply voltage from the back side (or the second side) of the semiconductor device 20 to the integrated circuit 210. The second power delivery network 230V includes a plurality of power lines (e.g., power lines 231a, 232a, and 23na) and a plurality of power vias (e.g., power vias 231v and 232v) coupled between the integrated circuit 210 and the terminals 250 at the back side. The power lines may be or include n layers of metal layers (e.g., BM1, BM2, and BMn, n may be an integer greater than 3). The second power supply voltage may be a positive voltage level (i.e., V_{DD}).

In some embodiments, the interconnection structure 230 further includes signal lines (e.g., signal lines 231b). The signal lines may be or include n layers of metal layers (e.g., BM1, BM2, and BMn, n may be an integer greater than 3). Each of the signal lines may be at the same elevation with one layer of the power lines.

In some embodiments, the terminals 240 and 250 are respectively at the first side (or the front side) and the second side of the semiconductor device 20 and configured to receive the first power supply voltage and the second power supply voltage, respectively, from a plurality of power sources outside of the semiconductor device 20. In some embodiments, the terminal 240 is at the front side of the semiconductor device 20 and configured to receive the first power supply voltage from the voltage source S1 (V_{SS}). In some embodiments, the terminal 250 is at the back side of the semiconductor device 20 and configured to receive the second power supply voltage from the voltage source S2 (V_{DD}).

The first power supply voltage may be provided from the front side of the semiconductor device 20 to the integrated circuit 210 along a path P1 passing the first power delivery network 220V including n layers of power lines, and the second power supply voltage may be provided from the back side of the semiconductor device 20 to the integrated circuit 210 along a path P2 passing the second power delivery network 230V including n layers of power lines.

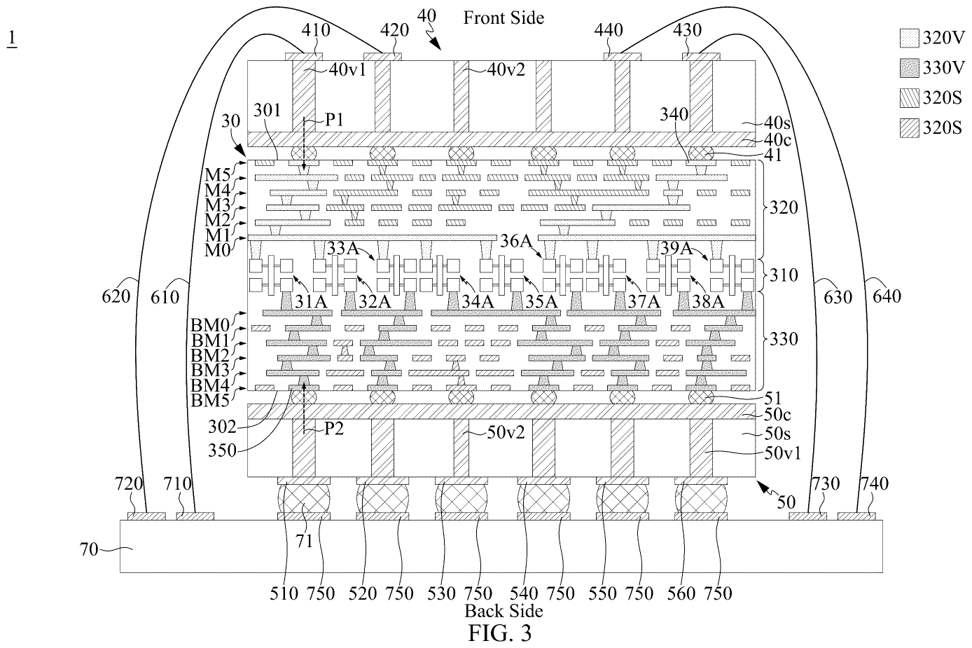

FIG. 3 is a cross-section of a package structure 1 according to one or more embodiments of the present disclosure. The package structure 1 may include semiconductor devices 30, 40, and 50, bonding wires 610, 620, 630, and 640, and a substrate 70. The package structure 1 may be referred to as a 3D stacked package.

The semiconductor device 30 includes an integrated circuit 310, interconnection structures 320 and 330, and conductive pads 340 and 350. In some embodiments, the integrated circuit 310 includes a plurality of CFETs (e.g., CFETs 31A, 32A, 33A, 34A, 35A, 36A, 37A, 38A, and 39A). The integrated circuit 310 is similar to the integrated circuit 110 and/or 210, and the CFETs 31A, 32A, 33A, 34A, 35A, 36A, 37A, 38A, and 39A are similar to the CFETs 11A, 11B, 21A, and/or 21B, and the description thereof is omitted hereinafter. The semiconductor device 30 may be or include a logic die.

The semiconductor device 30 has a surface 301 and a surface 302 opposite to the surface 301, and the semiconductor device 30 is configured to receive a first power supply voltage from the surface 301 and a second power supply voltage from the surface 302. In some embodiments, the conductive pad 340 is exposed by the surface 301, and the conductive pad 350 is exposed by the surface 302. The first power supply voltage may be a voltage of ground level or a voltage source supply (V_{SS}). The first power supply voltage may be a negative voltage level (i.e., V_{SS}). The second power supply voltage may be a positive voltage level (i.e., V_{DD}).

In some embodiments, the interconnection structure 320 includes a plurality of metal layers M0, M1, M2, M3, M4, and M5 and a plurality of conductive vias electrically connected to the metal layers at the front side of the CFETs. In some embodiments, the semiconductor device 30 or the interconnection structure 320 includes a power grid 320V (or a power delivery network) electrically coupling the conductive pads 340 to the CFETs. The power grid 320V may be or include portions of the metal layers M0, M1, M2, M3, M4, and M5 and portions of the conductive vias. In some embodiments, the semiconductor device 30 or the interconnection structure 320 further includes a signal routing structure 320S coupled between the conductive pads 340 and the CFETs. In some embodiments, the signal routing structure 320S may be or include portions of the metal layers M0, M1, M2, M3, M4, and M5 and portions of the conductive vias different from those of the power grid 320V.

In some embodiments, the power grid 320V includes a plurality of power lines at vertically different levels (e.g., the metal layers M0, M1, M2, M3, M4, and M5), and the signal routing structure 320S includes a plurality of signal lines at vertically different levels (e.g., the metal layers M0, M1, M2, M3, M4, and M5). In some embodiments, each of the signal lines is at the same level as each of the power lines.

In some embodiments, the interconnection structure 330 includes a plurality of metal layers BM0, BM1, BM2, BM3, BM4, and BM5 and a plurality of conductive vias electrically connected to the metal layers at the back side of the CFETs. In some embodiments, the semiconductor device 30 or the interconnection structure 330 includes a power grid 330V (or a power delivery network) electrically coupling the conductive pads 350 to the CFETs. The power grid 330V may be or include portions of the metal layers BM0, BM1, BM2, BM3, BM4, and BM5 and portions of the conductive vias. In some embodiments, the semiconductor device 30 or the interconnection structure 330 further includes a signal routing structure 330S coupled between the conductive pads 350 and the CFETs. In some embodiments, the signal routing structure 330S may be or include portions of the metal layers BM0, BM1, BM2, BM3, BM4, and BM5 and portions of the conductive vias different from those of the power grid 330V.

In some embodiments, the power grid 330V includes a plurality of power lines at vertically different levels (e.g., the metal layers BM0, BM1, BM2, BM3, BM4, and BM5), and the signal routing structure 330S includes a plurality of signal lines at vertically different levels (e.g., the metal layers BM0, BM1, BM2, BM3, BM4, and BM5). In some embodiments, each of the signal lines is at the same level as each of the power lines.

In some embodiments, the semiconductor device 40 includes a substrate layer 40s, a circuit layer 40c on a front surface of the substrate layer 40s, conductive pads 410, 420, 430, and 440 on a back surface of the substrate layer 40s, and through silicon vias (TSVs) 40v1 and 40v2 penetrating the substrate layer 40s to connect the circuit layer 40c to the conductive pads 410-440. In some embodiments, the TSVs 40v1 and 40v2 are connected to the surface 301 of the semiconductor device 30. The TSVs 40v1 may be power vias, the TSV 40v2 may be signals vias, and a width of the TSVs 40v1 is greater than a width of the TSVs 40v2.

In some embodiments, the semiconductor device 50 includes a substrate layer 50s, a circuit layer 50c on a front surface of the substrate layer 50s, conductive pads 510, 520, 530, 540, 550, and 560 on a back surface of the substrate layer 50s, and through silicon vias (TSVs) 50v1 and 50v2 penetrating the substrate layer 50s to connect the circuit layer 50c to the conductive pads 510-560. The TSVs 50v1 may be power vias, the TSV 50v2 may be signals vias, and a width of the TSVs 50v1 is greater than a width of the TSVs 50v2.

The bonding wires 610, 620, 630, and 640 may electrically connect the semiconductor device 40 to the substrate 70. The substrate 70 may be or include a printed circuit board (PCB). In some embodiments, the substrate 70 includes conductive pads 710, 720, 730, 740, and 750. In some embodiments, the bonding wire 610 electrically connects the conductive pad 710 to the conductive pad 410. In some embodiments, the bonding wire 620 electrically connects the conductive pad 720 to the conductive pad 420. In some embodiments, the bonding wire 630 electrically connects the conductive pad 730 to the conductive pad 430. In some embodiments, the bonding wire 640 electrically connects the conductive pad 740 to the conductive pad 440.

In some embodiments, the TSVs 40v1 are connected to the surface 301 of the semiconductor device 30 and configured to provide the first power supply voltage. In some embodiments, the bonding wires 610 and 630 electrically connect the conductive pads 710 and 730 to the conductive pads 410 and 430 to provide the first power supply voltage to the surface 301 of the semiconductor device 30. The path P1 for providing the first power supply voltage may pass the TSV 40v1, a conductive bump 41, and the power grid 320V.

In some embodiments, the substrate 70 is connected to the surface 302 of the semiconductor device 30 and configured to provide the first power supply voltage. In some embodiments, the conductive pads 750 electrically connect to the TSVs 50v1 to provide the second power supply voltage to the surface 302 of the semiconductor device 30. The path P2 for providing the second power supply voltage may pass a solder ball 71, the TSV 50v1, and the power grid 330V.

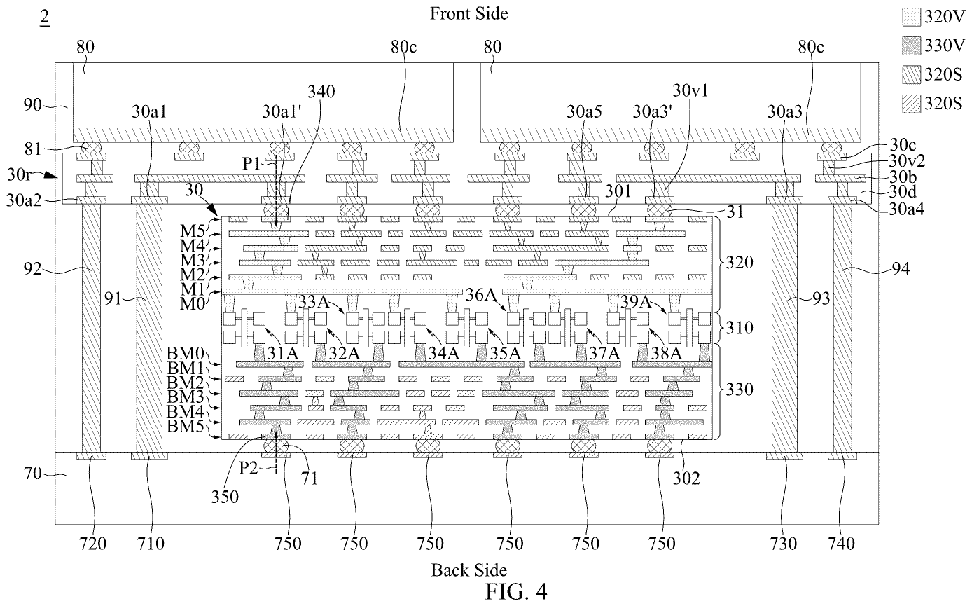

FIG. 4 is a cross-section of a package structure 2 according to one or more embodiments of the present disclosure. The package structure 2 illustrated in FIG. 4 is similar to the package structure 1 illustrated in FIG. 3, and the differences therebetween are described as follows.

The package structure 2 may further include a redistribution layer (RDL) 30r, semiconductor devices 80, a molding layer 90, and conductive pillars 91, 92, 93, and 94.

In some embodiments, the RDL 30r is connected to the surface 301 of the semiconductor device 30 and configured to provide the first power supply voltage. In some embodiments, the RDL 30r includes a dielectric structure 30d, conductive layers 30b, conductive pads 30a1 30a ′, 30a2, 30a40 , 30a3′, 30a′, and 30a5, and conductive vias 30v1 and 30v2. In some arrangements, the RDL 30r is electrically connected to the semiconductor device 30 through conductive bumps 31. In some embodiments, the conductive pillars 91, 92, 93, and 94 electrically connect the RDL 30r to the substrate 70.

In some embodiments, the conductive pillar 91 electrically connects the conductive pad 710 to the conductive pad 30a1. In some embodiments, the conductive pillar 92 electrically connects the conductive pad 720 to the conductive pad 30a2. In some embodiments, the conductive pillar 93 electrically connects the conductive pad 730 to the conductive pad 30a3. In some embodiments, the conductive pillar 94 electrically connects the conductive pad 740 to the conductive pad 30a4.

In some embodiments, the conductive pads 30a1′ and 30a2′ are connected to the surface 301 of the semiconductor device 30 and configured to provide the first power supply voltage. In some embodiments, the conductive pillars 91 and 93 electrically connect the conductive pads 710 and 730 to the conductive pads 31a1 and 30a2, which are respectively electrically connected to the conductive pads 30a1′ and 30a2′ through portions of the conductive layers 30b and the conductive vias 30v1 to provide the first power supply voltage to the surface 301 of the semiconductor device 30. The path P1 for providing the first power supply voltage may pass the conductive via 30v1, a conductive bump 31, and the power grid 320V. The first power supply voltage may be a voltage of ground level or a voltage source supply (V_{SS}). The first power supply voltage may be a negative voltage level (i.e., V_{SS}).

In some embodiments, the substrate 70 is connected to the surface 302 of the semiconductor device 30 and configured to provide the first power supply voltage. In some embodiments, the conductive pads 750 electrically connect to the conductive pads 350 to provide the second power supply voltage to the surface 302 of the semiconductor device 30. The path P2 for providing the second power supply voltage may pass a solder ball 71 and the power grid 330V. The second power supply voltage may be a positive voltage level (i.e., V_{DD}).

In some embodiments, the semiconductor devices 80 are disposed on and electrically connected to the RDL 30r. In some embodiments, the semiconductor device 80 includes a circuit layer 80c electrically connected to the conductive pads 30c through conductive bumps 81. In some embodiments, the molding layer 90 covers or encapsulates the semiconductor devices 30 and 80, the RDL 30r, and the conductive pillars 91, 92, 93, and 94. The semiconductor devices 80 may be or include memory components, e.g., HBMs.

Some embodiments of the present disclosure provide a semiconductor device. The semiconductor device includes an integrated circuit, a first power delivery network, and a second power delivery network. The integrated circuit includes at least a complementary field effect transistor. The semiconductor device has a first side and a second side on opposite sides of the complementary field effect transistor. The first power delivery network is configured to provide a first power supply voltage from the first side of the semiconductor device to the integrated circuit. The second power delivery network is configured to provide a second power supply voltage from the second side of the semiconductor device to the integrated circuit.

Some embodiments of the present disclosure provide a semiconductor device. The semiconductor device includes a plurality of complementary field effect transistors, a first interconnection structure, and a second interconnection structure. The first interconnection structure is configured to receive a first power supply voltage from a first side of the semiconductor device. The second interconnection structure is configured to receive a second power supply voltage from a second side of the semiconductor device. The first side and the second side of the semiconductor device are on opposite sides of the plurality of complementary field effect transistors.

Some embodiments of the present disclosure provide a package structure. The package structure includes a first semiconductor device. The first semiconductor device includes a plurality of complementary field effect transistors and has a first surface and a second surface opposite to the first surface. The first semiconductor device is configured to receive a first power supply voltage from the first surface and a second power supply voltage from the second surface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
an integrated circuit comprising at least a complementary field effect transistor, wherein the semiconductor device has a first side and a second side on opposite sides of the complementary field effect transistor;
a first power delivery network configured to provide a first power supply voltage from the first side of the semiconductor device to the integrated circuit; and
a second power delivery network configured to provide a second power supply voltage from the second side of the semiconductor device to the integrated circuit.

2. The semiconductor device of claim 1, wherein the first power delivery network is at a first side of the integrated circuit, and the second power delivery network is at a second side opposite to the first side of the integrated circuit.

3. The semiconductor device of claim 1, further comprising a plurality of first signal lines coupled to the integrated circuit, wherein the first power delivery network comprises a first power rail at an elevation the same as that of the first signal lines.

4. The semiconductor device of claim 3, further comprising a plurality of second signal lines coupled to the integrated circuit, wherein the second power delivery network comprises a second power rail at an elevation the same as that of the second signal lines.

5. The semiconductor device of claim 4, wherein the first power rail and the second power rail extend substantially in parallel.

6. The semiconductor device of claim 3, wherein a width of the first signal lines is less than a width of the first power rail.

7. The semiconductor device of claim 1, wherein the semiconductor device is free of a power via configured to provide power from the first power delivery network to the second power delivery network.

8. A semiconductor device, comprising:
a plurality of complementary field effect transistors;
a first interconnection structure configured to receive a first power supply voltage from a first side of the semiconductor device; and
a second interconnection structure configured to receive a second power supply voltage from a second side of the semiconductor device, the first side and the second side of the semiconductor device being on opposite sides of the plurality of complementary field effect transistors.

9. The semiconductor device of claim 8, wherein the first interconnection structure comprises:
a first power rail;
a first power via coupled between the first power rail and one of the complementary field effect transistors; and
a plurality of first signal lines coupled to the complementary field effect transistors and at an elevation the same as that of the first power rail.

10. The semiconductor device of claim 9, wherein a width of the first power rail is greater than a width of the first signal lines.

11. The semiconductor device of claim 9, wherein the first interconnection structure further comprises a plurality of first signal vias coupled between the first signal lines and the complementary field effect transistors, wherein a width of the first power via is greater than a width of the first signal vias.

12. The semiconductor device of claim 8, wherein the first interconnection structure comprises a first power grid configured to receive the first power supply voltage, the second interconnection structure comprises a second power grid configured to receive the second power supply voltage, and a ratio of an amount of routing resource taken by the first power grid to an amount of routing resource taken by the second power grid is from about 80% to about 120%.

13. The semiconductor device of claim 12, wherein the first power grid is coupled between the first side of the semiconductor device and the plurality of complementary field effect transistors, and the second power gird is coupled between the second side of the semiconductor device and the plurality of complementary field effect transistors.

14. The semiconductor device of claim 8, further comprising a first terminal and a second terminal respectively at the first side and the second side of the semiconductor device and configured to receive the first power supply voltage and the second power supply voltage, respectively, from a plurality of power sources outside of the semiconductor device.

15. A package structure, comprising:
a first semiconductor device comprising plurality of complementary field effect transistors and having a first surface and a second surface opposite to the first surface, wherein the first semiconductor device is configured to receive a first power supply voltage from the first surface and a second power supply voltage from the second surface.

16. The package structure of claim 15, wherein the first semiconductor device further comprises:
a first conductive pad exposed by the first surface;
a second conductive pad exposed by the second surface;
a first power grid electrically coupling the first conductive pad to the plurality of complementary field effect transistors; and
a second power grid electrically coupling the second conductive pad to the plurality of complementary field effect transistors.

17. The package structure of claim 16, wherein the first semiconductor device further comprises:
a first signal routing structure coupled between the first conductive pad and the plurality of complementary field effect transistors; and
a second signal routing structure coupled between the second conductive pad and the plurality of complementary field effect transistors.

18. The package structure of claim 17, wherein the first power grid comprises a first power line and a second power line at a vertically different level from the first power line, and the first signal routing structure comprises a first signal line at the same level as the first power line and a second signal line at the same level as the second power line.

19. The package structure of claim 15, further comprising:
a substrate connected to the first surface of the first semiconductor device and configured to provide the first power supply voltage;
a second semiconductor device comprising a through silicon via and connected to the second surface of the first semiconductor device and configured to provide the second power supply voltage; and
a bonding wire electrically connecting the second semiconductor device to the substrate.

20. The package structure of claim 15, further comprising:
a substrate connected to the first surface of the first semiconductor device and configured to provide the first power supply voltage;
a redistribution layer connected to the second surface of the first semiconductor device and configured to provide the second power supply voltage; and
a conductive pillar electrically connecting the redistribution layer to the substrate.
